(19) United States
(12) Patent Application Publication
(10) Pub. No.: US 2026/0219751 A1
(43) Pub. Date: Jul. 30, 2026

(54) PSEUDO-DIFFERENTIAL ATTENUATOR ARCHITECTURE FOR SINUSOIDAL CHANNEL

(71) Applicant: Cypress Semiconductor Corporation, San Jose, CA (US)

(72) Inventors: Syed Tabish Alam, Cork (IE); Khosrov Sadeghipour, Ballincollig (IE); Daniel O'Keeffe, Cork (IE); Viktor Kremin, Lviv (UA); Sean O'Sullivan, Clonakilty (IE); Matheus Ferreira Pimenta, Cork (IE)

(73) Assignee: Cypress Semiconductor Corporation, San Jose, CA (US)

(21) Appl. No.: 19/039,009

(22) Filed: Jan. 28, 2025

(51) Int. Cl. G06F 3/041; G06F 3/044

(52) U.S. Cl. CPC G06F 3/0416; G06F 3/0443; G06F 3/0446

(57) ABSTRACT

An integrated circuit includes a plurality of receiver (RX) sensing circuits, each coupled to an RX electrode of a touch panel. Each RX sensing circuit can include an attenuator to receive a touch signal from the RX electrode and generate an attenuated current, a cross-coupled current mirror coupled to the attenuator, the cross-coupled current mirror to output a reverse current of the attenuated current, and a summer to combine the attenuated current with the reverse current from a neighbor RX sensing circuit of the plurality of RX sensing circuits.

### TECHNICAL FIELD

Embodiments of the present invention relate to the field of user interface devices and, in particular, to pseudo-differential attenuator architecture for a sinusoidal channel.

### BACKGROUND

Computing devices, such as notebook computers, personal data assistants (PDAs), and mobile handsets, have user interface devices, which are also known as human interface devices (HID). One type of user interface device that has become more common is touch-sensing devices, such as touch-sensor pads (also commonly referred to as touchpads), touch-sensor sliders, touch-sensor buttons, touch-sensor keyboard, touchscreens, and touch panels.

A basic notebook touch-sensor pad emulates the function of a personal computer (PC) mouse. A touch-sensor pad is typically embedded into a PC notebook for built-in portability. A touch-sensor pad replicates mouse x/y movement by using two defined axes which contain a collection of sensor elements that detect the position of a conductive object, such as a finger. Mouse right/left button clicks can be replicated by two mechanical buttons, located in the vicinity of the touchpad, or by tapping commands on the touch-sensor pad itself. The touch-sensor pad provides a user interface device for performing such functions as positioning a pointer or selecting an item on a display.

Another user interface device that has become more common is a touch screen. Touch screens, also known as touchscreens, touch panels, or touchscreen panels are display overlays, which are typically pressure-sensitive (resistive), electrically sensitive (capacitive), acoustically sensitive (SAW-surface acoustic wave), or photo-sensitive (infra-red). The effect of such overlays allows a display to be used as an input device, removing the keyboard and/or the mouse as the primary input device for interacting with the display's content. Such displays can be attached to computers or, as terminals, to networks. There are several types of touch screen technology, such as optical imaging, resistive, surface wave, capacitive, infrared, dispersive signal, and strain gauge technologies. Touch screens have become familiar in retail settings, on point-of-sale systems, automatic teller machines, mobile handsets, game consoles, and personal digital assistants. A stylus is sometimes used to manipulate the graphical user interface (GUI) and to enter data.

In general, capacitance-sensing devices are intended to replace mechanical buttons, knobs, and other similar mechanical user-interface controls. Capacitance-sensing devices eliminate the complicated mechanical switches and buttons, providing reliable operation under harsh conditions. In addition, capacitance-sensing devices are widely used in modern customer applications, providing new user interface options in the existing products. Capacitive touch sensor elements can be arranged in the form of a sensor array for a touch-sensing surface. When a conductive object, such as a finger, comes in contact or close proximity with the touch-sensing surface, the capacitance of one or more capacitive touch sensor elements changes. An electrical circuit can measure the capacitance changes of the capacitive touch sensor elements. The electrical circuit, supporting one operation mode, converts the measured capacitances of the capacitive touch sensor elements into digital values.

There are two main operational modes in the capacitance-sensing circuits: self-capacitance sensing and mutual capacitance sensing. The self-capacitance sensing mode is also called single-electrode sensing mode, as each sensor element needs only one connection wire to the sensing circuit. For the self-capacitance sensing mode, touching the sensor element increases the sensor capacitance as the finger capacitance of a touch signal is added to the sensor capacitance. The mutual capacitance change is detected in the mutual capacitance-sensing mode, also called all-points accessible mutual capacitance-sensing mode. Each sensor element uses at least two electrodes: one is a transmitter (TX) electrode (also referred to herein as transmitter electrode), and the other is a receiver (RX) electrode. When a finger touches a sensor element or is in close proximity to the sensor element, the capacitive coupling between the receiver and the transmitter of the sensor element is decreased as the finger shunts part of the electric field to ground (e.g., chassis or earth). This finger capacitance triggers sensing a mutual capacitance change at a particular intersection of the TX and RX electrodes.

### BRIEF DESCRIPTION OF THE DRAWINGS

The present disclosure is illustrated by way of example, and not by way of limitation, in the figures of the accompanying drawings.

FIG. 1A is a schematic block diagram of a system having a capacitance-sensing device with capacitance-sensing circuitry that drives a touch panel with differential or other types of sinusoidal drive signals according to some embodiments.

FIG. 1B is a diagram of the touch screen of FIG. 1A illustrating a difference between self-capacitance and mutual-capacitance according to some embodiments.

FIG. 2A is a schematic block diagram of RX sensing circuits of RX sensing circuitry according to some embodiments.

FIG. 2B is a schematic block diagram of RX sensing circuits of RX sensing circuitry according to other embodiments.

FIG. 3 is a schematic block diagram of the addition of a by-pass path for the reverse current of at least some of the RX sensing circuits according to some embodiments.

FIG. 4 is a schematic block diagram of a cross-coupled current mirror according to some embodiments.

FIG. 5 is a flow diagram of an embodiment of a method for reducing self-capacitance of a touch panel according to some embodiments.

FIG. 6 illustrates an embodiment of a core architecture of the PSoC® processing device, such as that used in the PSoC3® family of products offered by Cypress Semiconductor Corporation (San Jose, California).

### DETAILED DESCRIPTION

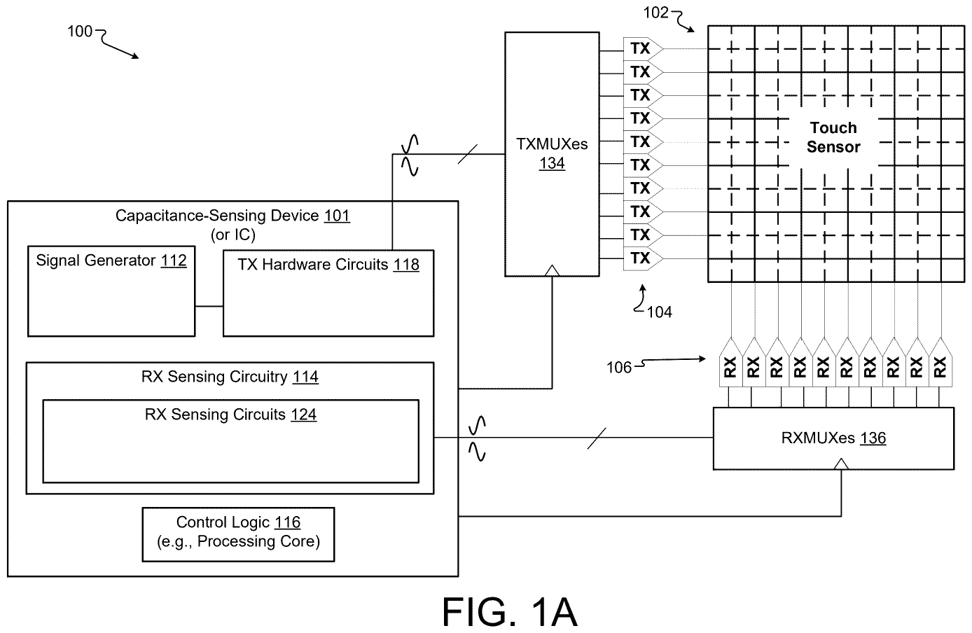

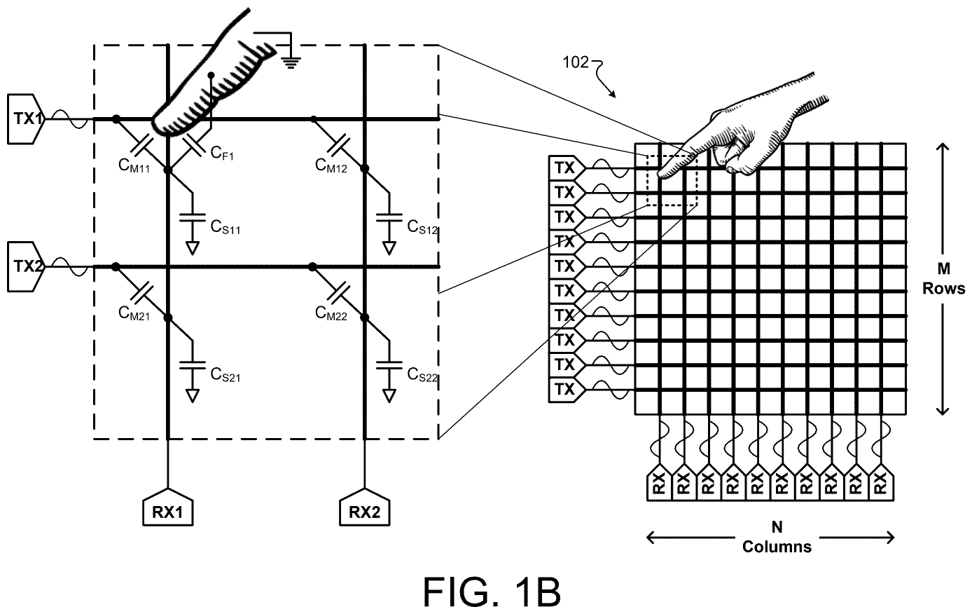

Touch panels (e.g., touch screens) that are used in consumer electronics and automotive settings are increasingly utilizing larger screen sizes, for example, greater than 12.3 inches. Some of such panels or screens now experience large self-parasitic capacitance, which contributes to overly large self-capacitance, for example, that is larger than mutual capacitance (see FIG. 1B). Touch devices or systems need to compensate for (i.e., at least partially remove) the self-capacitance when endeavoring to detect mutual capacitance associated with a touch.

Attempting to attenuate a signal that reduces the overall charge sensed at RX electrodes, however, reduces integrated finger capacitance as well. Due to the large parasitic capacitance, the integrated finger capacitance should be compensated to accommodate the dynamic range of the analog-to-digital converter (ADC) that is coupled to an RX channel of each RX electrode. For example, Equation (1) expresses the output charge from an RX electrode, which includes unwanted charge from self-capacitance (C_{Sj}) and the touch signal itself (C_{Fj}), where K_{ATIN} is an attenuation constant.

$$\vert QOUT \vert = \frac{{C}_{S j} \cdot V + {C}_{F j} \cdot V}{{K}_{A T T N}} \qquad ( 1 )$$

In the present disclosure, assume that the self-capacitance is much larger than the touch signal, as expressed in Equation (2), where M is the number of electrodes.

$${C}_{S j} = ( {\sum }_{i = 1}^{M} {C}_{S j} ) >> {C}_{F j} \qquad ( 2 )$$

As the output charge is increased, this limits the headroom of the ADC, attenuating the signal, for example, causing K_{ATIN} to increase, which reduces the signal as well, resulting in lower signal-to-noise ratio (SNR).

In some systems, baseline current sources are used to cancel out the self-capacitance. For example, current digital-to-analog converters (I_{DACs}) can be employed to ensure input current is stable at a particular direct-current (DC) range. To do so, circuitry can be configured to divide a clock to set particular frequencies to control switches to these I_{DACs}. Equations (3) and (4) illustrate how the current I_{DAC} value can be employed to substantially eliminate the self-capacitance.

$$\vert QOUT \vert = \frac{{C}_{S j} \cdot V + {C}_{F j} \cdot V - \frac{- {I}_{DAC} \cdot N}{{F}_{CLK}}}{{K}_{A T T N}^{′}} \qquad ( 3 )$$

$${C}_{Sj} \cdot V \approx \frac{{I}_{DAC} \cdot N}{{F}_{CLK}} \to \vert QOUT \vert \approx \frac{{C}_{Fj} \cdot V}{{K}_{A T T N}^{′}} where {K}_{A T T N}^{′} << {K}_{ATTN} \qquad ( 4 )$$

This approach, however, requires high-precision I_{DACs}, a small least significant bit (LSB) range, and a large dynamic range. Further, the I_{DACs} create a noise issue, requiring a low-jitter clock and a precise timing circuit. Additionally, this approach requires tuning for a variety of panel sizes and configurations, making the approach complex and challenging from a design and performance perspective.

Aspects of the present disclosure and embodiments overcome the deficiencies discussed above and others by generating, in each RX sensing circuit coupled to a respective RX electrode, a reverse current of the attenuated current. In such embodiments, each RX sensing circuit passes the reverse current to a neighbor RX sensing circuit for use in canceling out the self capacitance within each respective neighbor RX sensing circuit.

For example, in some embodiments, each RX sensing circuit of multiple RX sensing circuit (each coupled to an RX electrode) includes an attenuator to receive a touch signal from the RX electrode and generate an attenuated current. In such embodiments, each RX sensing circuit includes a cross-coupled current mirror coupled to an attenuator, the cross-coupled current mirror to output a reverse current of the attenuated current. In some embodiments, the reserve current is referred to as negative current that flows in the opposite direction of the attenuated current. Each RX sensing circuit can further include a summer to combine the attenuated current with the reverse current from a neighbor RX sensing circuit of the multiple RX sensing circuits. In some embodiments, for example, the multiple RX sensing circuits are ordered serially from a first side of the touch panel to a second side of the touch panel, and the reverse current of each RX sensing circuit is routed to the summer of a neighbor RX sensing circuit in a direction towards the first side. In embodiments, the second attenuator of a second RX sensing circuit can route its reverse current to the first RX sensing circuit in the series of sensing circuits, so that even the first RX sensing circuit receives a reverse current.

By way of advantages, in the present architecture, because the reverse current from a neighbor RX sensing circuit includes a self-capacitance that substantially matches the self-capacitance of a respective RX sensing circuit, each RX sensing circuit is able to substantially cancel (or at least significantly reduce) the self-capacitance associated with a coupled electrode. By substantially eliminating the large self-capacitance, the smaller finger capacitance can be properly detected, indicating a touch signal being sensed, e.g., by detecting a change in expected mutual capacitance. Further, with the addition of minimal circuitry, if it is detected that a given RX sensing circuit is defective or its RX pin is not used, the reverse current from its neighbor RX sensing circuit can bypass the defective (or unused) RX sensing circuit to the next neighbor RX sensing circuit. In this way, the present architecture can ensure that each functional RX sensing circuit gets a reverse current from which to cancel self-capacitance from a coupled electrode.

By way of further advantages, the present architecture does not require an I_{DAC} or additional baselining circuitry, thus eliminating the typical noise associated with these approaches. The charge subtraction of the self and parasitic capacitances can be performed by hardware circuitry, thus can be done with high performance and less likelihood of error. Further, no tuning is required for different panel sizes and configurations and it is not necessary to employ a panel shield layer.

It should be noted that the capacitance-sensing circuitry can detect conductive objects and other objects (also referred to as touch objects). An object, or touch object, is any object that disturbs the electrical field and reduces the coupling between the receiver and transmitter electrodes for the capacitance sensing techniques. For example, if a user touches the touch surface wearing gloves, the capacitance-sensing circuitry may not detect the user's finger as a conductive object, but the capacitance-sensing circuitry can still detect the user's finger because the user's finger still disturbs the electrical field and reduces the coupling between the electrodes. It should also be noted that the embodiments described herein can be used on touch panels having more than two transmitter electrodes and receiver electrodes as described below. Also, the capacitance-sensing circuitry can detect a hover event of a conductive object above the touch panel.

The following description sets forth numerous specific details, such as examples of specific systems, components, methods, and so forth, in order to provide a good understanding of several embodiments of the present invention. However, it will be apparent to one skilled in the art that at least some embodiments of the present invention may be practiced without these specific details. In other instances, well-known components or methods are not described in detail or presented in a simple block diagram format to avoid unnecessarily obscuring the present invention. Thus, the specific details set forth are merely exemplary. Particular implementations may vary from these exemplary details and still be contemplated to be within the spirit and scope of the present invention.

References in the description to “one embodiment” or “an embodiment” means that a particular feature, structure, or characteristic described in connection with the embodiment is included in at least one embodiment of the invention. The appearances of the phrase “in one embodiment” in various places in the specification do not necessarily all refer to the same embodiment.

FIG. 1A is a block diagram of a system 100 having a capacitance-sensing device 101 with capacitance-sensing circuitry that drives a touch panel 102 with differential or other types of sinusoidal drive signals according to some embodiments. For example, the capacitance-sensing device 101 can support other capacitance-sensing modes, such as mutual capacitance or self capacitance. FIG. 1A illustrates the capacitance-sensing device 101 with a touch-controller architecture having a sensing grid (e.g., a sense panel, the touch panel 102, or a capacitance matrix) with a rectangular array of sense electrodes. The rectangular array of sense electrodes can include an integer number, M, of TX electrodes 104 and an integer number, N, of RX electrodes 106 capacitively coupled to the TX electrodes 104.

In some embodiments, the capacitance-sensing device 101 includes capacitance-sensing circuitry, which can be capable of one or both transmitting and receiving as will be discussed. In some embodiments, the capacitance-sensing device 101 includes a signal generator 112, TX hardware circuits 118, RX sensing circuitry 114, and control logic 116 such as one or more processing cores. In embodiments, the RX sensing circuitry 114 includes RX sensing circuits 124 that can also be implemented in hardware, for example.

In one embodiment, for example, the number of TX electrodes is between 30-50 electrodes and the number of RX electrodes can range between 40-60 electrodes (although could include 100 RX electrodes or more in some embodiments). In other embodiments, the number of RX electrodes matches or approximately matches the number of TX electrodes. In some embodiments, the system 100 (or device 101) includes multiplexers to connect the panel electrodes to one or more sense channels and multiplex signals between the number of RX electrodes and the number of TX electrodes. For example, the system 100 (or device 101) can include a plurality of TX multiplexers 134 coupled between the TX hardware circuits 118 and the TX electrodes 104, to multiplex selection between in-phase and opposite-phase TX drive signals when functioning in multi-phase TX mode. Further, the system 100 (or device 101) can include a plurality of RX multiplexers 136 coupled between the RX sensing hardware circuits 124 and the RX electrodes 106, to multiplex receipt of sense signals from the RX electrodes 106.

In embodiments, the signal generator 112 generates a drive signal such as a sinusoidal drive signal or a square wave signal in differing embodiments. In some embodiments, the sinusoidal drive signal is a sine wave, a cosine wave, or the like, to be driven over each TX electrode 104. In some embodiments, the drive signal includes an in-phase drive signal and an opposite-phase drive signal in multi-phase TX mode, and selects an excitation sequence with a number of positive and negative ones, corresponding to the in-phase drive signals and the opposite-phase drive signals, respectively. The excitation sequence can be selected such that the sum of the excitation sequence is zero. Alternatively, the excitation sequence can be selected such that the sum is not zero. In the case where the excitation sequence has a sum of zero, the excitation sequence can be referred to as a zero-sum excitation sequence.

At the first scanning stage, the signal generator 112 can apply an in-phase drive signal to one or more TX electrodes 104 simultaneously and according to the excitation sequence. Also, at the first scanning stage, the signal generator 112 can optionally apply an opposite-phase drive signal to one or more TX electrodes 104 simultaneously and according to the excitation sequence. The signal generator 112 can apply the in-phase drive signal and the opposite-phase drive signal to adjacent TX electrodes 104 in at least one embodiment.

In some embodiments, the RX sensing circuits 124 are multiplied to provide a particular number of sensing channels corresponding to the RX electrodes 106. Each RX sensing circuit 124 can include hardware configured to detect a presence of an object (such as a finger or other conductive object) on or near the touch panel 102 of capacitance-sensing device 101. The sense signals represent capacitances associated with the RX electrodes 106, which can be altered in response to a touch or hovering action.

FIG. 1B is a diagram of the touch screen 102 of FIG. 1A illustrating a difference between self-capacitance and mutual-capacitance according to some embodiments. As is illustrated, by cancelling a baseline charge associated with the self capacitance (C_{Sij}), the RX sensing circuitry 114 is able to keep the finger charge (C_{Fi}) integrated with the mutual capacitance (C_{Mij}), thus enabling proper sensing by the RX sensing circuits 124 of a touch or hover action that causes the finger charge.

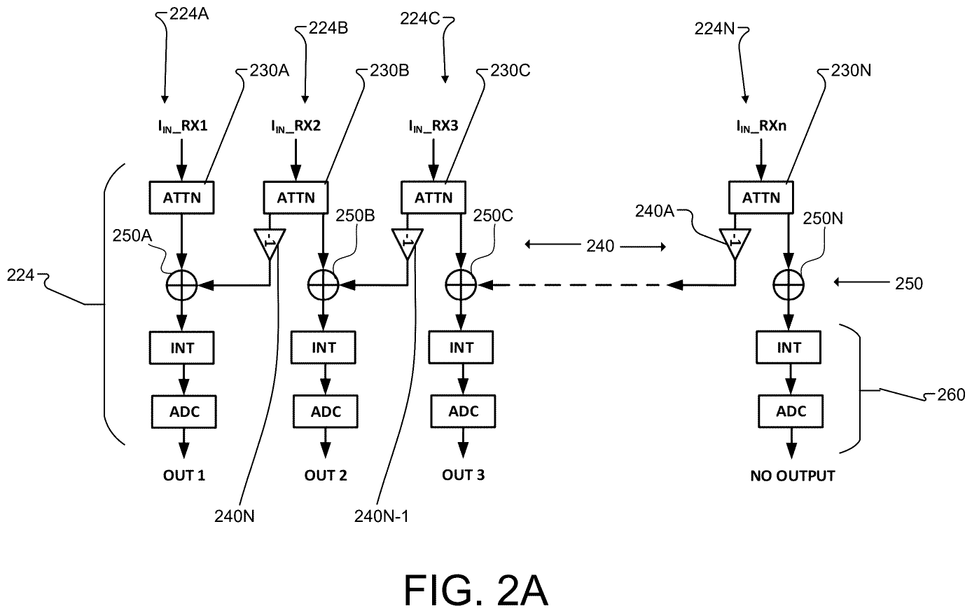

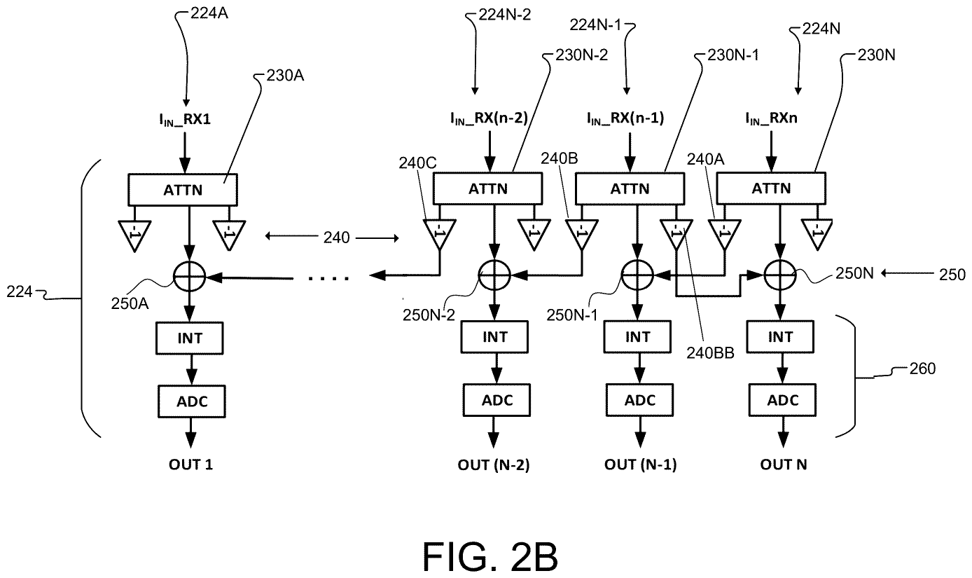

FIG. 2A is a schematic block diagram of RX sensing circuits 224 of RX sensing circuitry, e.g., the RX sensing circuitry 114 of FIG. 1A according to some embodiments. In some embodiments, each RX sensing circuit 224 is one of the multiple RX sensing circuits 124 of FIG. 1A. Just by way of example, the RX sensing circuits 224 each include an attenuator to receive a touch signal from the RX electrode to which the RX sensing circuit is coupled and generate an attenuated current.

For example, in embodiments, the RX sensing circuits 224 can include a first RX sensing circuit 224A having a first attenuator 230A to generate a first attenuated current, a second RX sensing circuit 224B having a second attenuator 230B to generate a second attenuated current, a third RX sensing circuit 224C having a third attenuator 230C to generate a third attenuated current, and an Nth RX sensing circuit 224N having an Nth attenuator 230N to generate an Nth attenuated current, where “Nth” can mean final or last. In some embodiments, the RX sensing circuits 224 are ordered serially from a first side (or left side) of the touch panel 102 to a second side (or right side) of the touch panel 102, e.g., from the first RX sensing circuit 224A to the Nth RX sensing circuit 230N.

In at least some embodiments, each RX sensing circuit 224, except for the first RX sensing circuit 224A, includes a cross-coupled current mirror 240 coupled to the attenuator (i.e. 230A-230N), the cross-coupled current mirror 240 to output a reverse current of the attenuated current, also referred to as a negative current. Such a reverse current flows in the opposite direction as the attenuated current and can be routed or passed to a neighbor RX sensing circuit, e.g., in this embodiment, from the second side to the first side of the touch panel 102. In this context, a “neighbor” means adjacent to without an intervening RX sensing circuit. Thus, the cross-coupled current mirrors can be ordered in a reverse direction from the other hardware in each RX sensing circuit, as explained herein. In such embodiments, the first RX sensing circuit 224A does not need to include a cross-coupled mirror because the first RX sensing circuit 224A does not have a neighbor RX sensing circuit to the left, e.g., towards the first side.

Further, each RX sensing circuit 224 can include a summer 250 to combine the attenuated current from the attenuator with the reverse current from a neighbor RX sensing circuit of the multiple RX sensing circuits 224. Thus, according to the illustrated embodiment, the Nth RX sensing circuit 230N does not receive a reverse current, but chances of receiving a touch on the very edge of the touch panel 102 are low. Each of the other RX sensing circuits 224 can, however, receive a reverse current from its neighbor.

For example, in embodiments, the first RX sensing circuit 224A includes a first summer 250A to combine the first attenuated current with a reverse current from an Nth cross-coupled current mirror 240N of the second RX sensing circuit 224B. Further, the second RX sensing circuit 224B can include a second summer 250B to combine the second attenuated current with a reverse current from an N−1 cross-coupled current mirror 240N−1 of the third RX sensing circuit 224C. Additionally, the third RX sensing circuit 224C can include a third summer 250C to combine the third attenuated current with a reverse current from an N−2 cross-coupled current mirror of a fourth RX sensing circuit (not illustrated). This routing of the neighbor reverse current can continue across the RX sensing circuits 224 of the touch panel 102, until the N−1th RX sensing circuit (not illustrated) that has a summer to combine the reverse current from a first cross-coupled current mirror 240A of the Nth RX sensing circuit 224N. In this way, the reverse current of each RX sensing circuit 224 can be routed to the summer of a neighbor RX sensing circuit in a direction towards the first side.

In other embodiments, although not illustrated, the reverse current of each RX sensing circuit 224 is routed to the summer 250 of a neighboring RX sensing circuit in a direction towards the second side (or right side), thus in the opposite direction than the one illustrated. In these embodiments, at least the second RX sensing circuit 224B of the multiple RX sensing circuits 224 includes a second cross-coupled current mirror to provide the reverse current from the second RX sensing circuit to the first RX sensing circuit 224A of the multiple RX sensing circuits 224.

In some embodiments, each RX sensing circuit 224 further includes a combination of an integrator and an analog-to-digital converter (ADC) 260 coupled to the summer of that RX sensing circuit. In other embodiments, although not illustrated, each RX sensing circuit 224 instead includes a delta-sigma modulator coupled to the summer, e.g., where the delta-sigma modulator is designed to perform the function of the combination of the integrator and ADC 260.

In embodiments of the disclosed architecture, Equations (5), (6), and (7) illustrate how the cancellation of the neighboring reverse current (CF₍ⱼ₊₁₎·V) facilitates isolating the touch signal (C_{Fj}·V) with the finger capacitance (C_{Fj}) to be able to sense a touch at one or more electrodes of the touch panel 102.

$$\vert QOUTj \vert = \frac{{C}_{S j} \cdot V + {C}_{F j} \cdot V - {C}_{S ( j + 1 )} \cdot V}{{K}_{A T T N}^{′}} \qquad ( 5 )$$

$${C}_{S j} = {\sum }_{i = 1}^{M} {C}_{Sij} \approx {C}_{S ( j + 1 )} = {\sum }_{i = 1}^{M} {C}_{Si ( j + 1 )} \qquad ( 6 )$$

$$\vert QOUTj \vert \approx \frac{{C}_{Fj} \cdot V}{{K}_{A T T N}^{′}} where {K}^{′} ATTN << KATTN \qquad ( 7 )$$

FIG. 2B is a schematic block diagram of RX sensing circuits 224 of the RX sensing circuitry 114 according to other embodiments. As a variation to the embodiments of FIG. 2A, in FIG. 2B is illustrated an embodiment in which each RX sensing circuit 224 is manufactured with two cross-coupled current mirrors, e.g., so that a penultimate RX sensing circuit 224N−1 can generate the reverse current for both the last (or Nth) RX sensing circuit 224N and an N−2 RX sensing circuit 224N−2. For example, at least the penultimate RX sensing circuit 224N−1 of the multiple RX sensing circuits 224 includes a second cross-coupled current mirror 240B to generate the reverse current to be sent to the N−2 RX sensing circuit 230N−2. Additionally, the penultimate RX sensing circuit 224N−1 includes a third cross-coupled current mirror 240BB to generate the reverse current from the penultimate RX sensing circuit 224N−1 to the Nth summer 250N of the last RX sensing circuit 224N of the multiple RX sensing circuits 224. In this way, unlike in FIG. 2A, the final or last RX sensing circuit 224N receives the reverse current from the third cross-coupled current mirror 240BB, which is located in the penultimate RX sensing circuit 224N−1.

With additional reference to FIG. 2B, the penultimate RX sensing circuit 224N−1 also includes a penultimate attenuator 230N−1 to receive a touch signal from a coupled RX electrode and generate a penultimate attenuated current. The penultimate RX sensing circuit 224N−1 can also include a penultimate summer 250N−1 coupled to the penultimate attenuator 230N−1 to combine the penultimate attenuated current with the reverse current from the first cross-coupled current mirror 240A of the last RX sensing circuit 224N.

Additionally, the N−2 RX sensing circuit 224N−2 can include an N−2 attenuator 230N−2 to receive a touch signal from a coupled RX electrode and generate an N−2 attenuated current. The N−2 RX sensing circuit 224N−2 can further include an N−2 summer 250N−2 coupled to the N−2 attenuator 230N−2 to combine the N−2 attenuated current with the reverse current from a second cross-coupled current mirror 240B of the penultimate RX sensing circuit 224N−1.

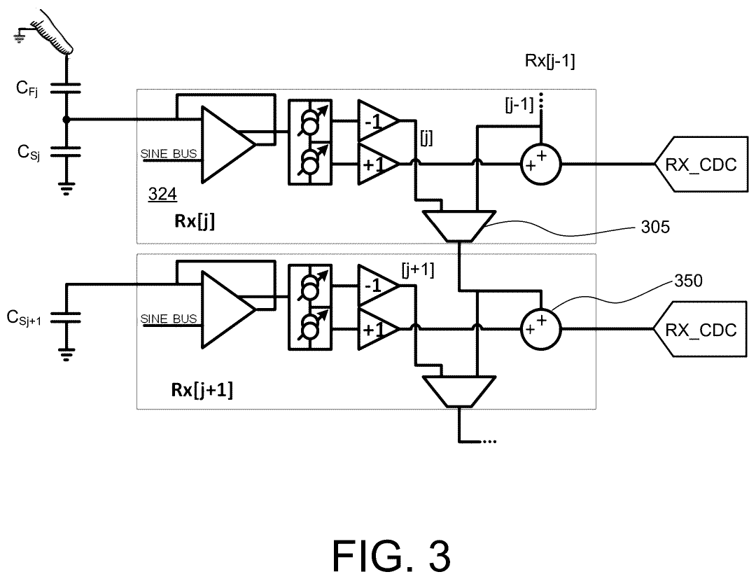

FIG. 3 is a schematic block diagram of the addition of a by-pass path for the reverse current of at least some of the RX sensing circuits according to some embodiments. In embodiments, each RX sensing circuit 324 (here represented by [j]) further includes a multiplexer 305 having inputs including a first reverse current from the RX sensing circuit 324 (e.g., from the cross-coupled current mirror thereof) and a second reverse current from an immediately preceding RX sensing circuit (e.g., [j−1]) of the multiple RX sensing circuits. In embodiments, an output of the multiplexer 305 is supplied to a sequentially ordered neighbor RX sensing circuit (e.g., [j+1]) of the multiple RX sensing circuits. Note that the RX sensing circuit 324 can be any of the RX sensing circuits 224 of FIGS. 2A-2B except perhaps the first RX sensing circuit 224A or the last RX sensing circuit 224N, because these need not include bypass paths in being at edges of the touch panel 102.

For example, in embodiments, the output of the multiplexer 305 is routed or supplied to a summer 350 of the sequentially ordered neighbor RX sensing circuit (e.g., [j+1]) to which is also supplied to the attenuated current of that neighbor RX sensing circuit. In this way, if the RX sensing circuit 324 becomes defective or its RX pin is not used for some reason, the RX sensing circuit 324 can be bypassed by controlling the multiplexer 305 to output the reverse current coming from the immediately preceding RX sensing circuit (e.g., [j−1]) of the multiple RX sensing circuits.

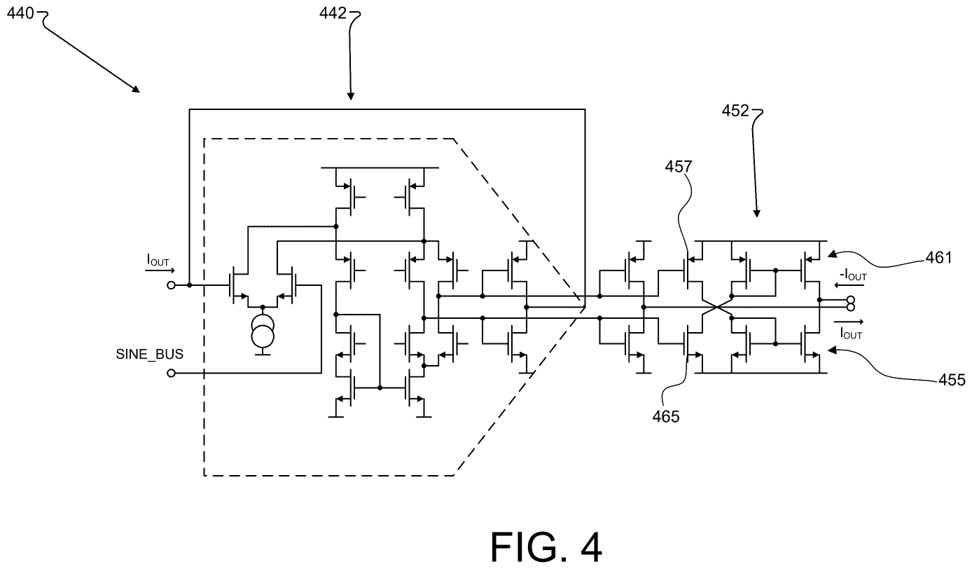

FIG. 4 is a schematic block diagram of a cross-coupled current mirror 440 according to some embodiments. For example, the cross-coupled current mirror 440 can represent the cross-coupled current mirrors 240A-240N of FIGS. 2A-2B and, in at least some embodiments, includes a current mirror 442 that outputs an input current to a cross-coupled current mirror stage 452. In embodiments, the cross-coupled current mirror stage 452 is coupled to an output of the current mirror 440 and has an output including the reverse current (−I_{OUT}) of the input current to the current mirror 442. Further, in some embodiments, the reverse current generated comes not only from a mirrored current but can also be scaled down to support several attenuation factors, thus making the cross-coupled current mirror 440 programmable as well, e.g., including trim settings for scaling the output currents.

In embodiments, the cross-coupling at the cross-coupled current mirror stage 452 is structured by coupling mutually-coupled gates of a pair of P-type transistors 461 to a drain of an N-type transistor 465 and to drain of one of the pair of N-type transistors 455. The cross-coupling current mirror stage 452 can further be structured by coupling mutually-coupled gates of a pair of N-type transistors 455 to a drain of a P-type transistor 457 and to a drain of the one of the pair of P-type transistors 461.

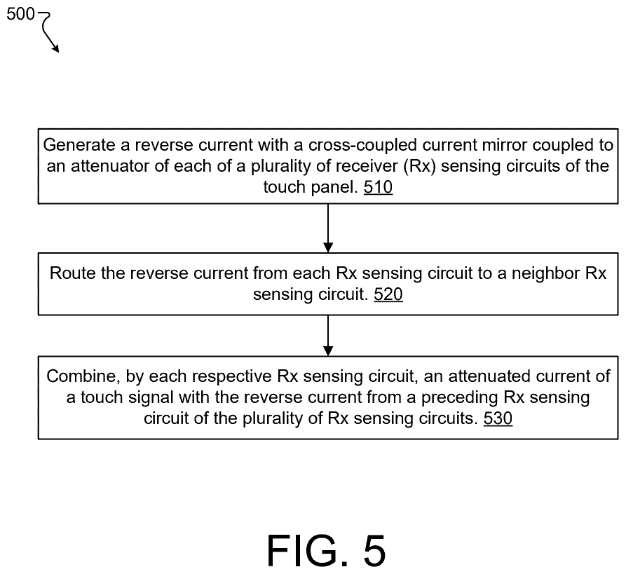

FIG. 5 is a flow diagram of an embodiment of a method 500 for reducing self-capacitance of a touch panel according to some embodiments. The method 500 can be performed by processing logic comprising hardware, firmware, or a combination thereof. The method 500 can be performed by the capacitance-sensing device 101 of FIGS. 1A-1B and/or by the system 100, as modified by circuitry illustrated in and discussed with reference to FIGS. 2A-4.

At operation 510, the method 500 includes generating a reverse current with a cross-coupled current mirror coupled to an attenuator of each of a plurality of receiver (RX) sensing circuits of the touch panel.

At operation 520, the method 500 includes routing the reverse current from each RX sensing circuit to a neighbor RX sensing circuit.

At operation 530, the method includes combining, by each respective RX sensing circuit, an attenuated current of a touch signal with the reverse current from a neighbor RX sensing circuit of the plurality of RX sensing circuits. In some embodiments, the neighbor RX sensing circuit is immediately following a given RX sensing circuit. In other embodiments, the neighbor RX sensing circuit is immediately preceding the given RX sensing circuit.

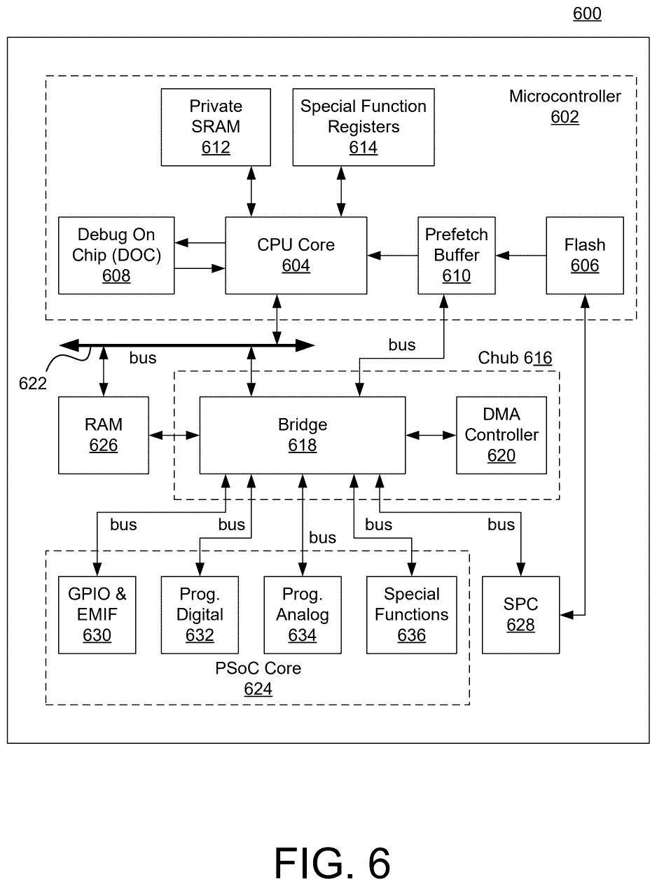

FIG. 6 illustrates an embodiment of a core architecture 600 of the PSoC® processing device, such as that used in the PSoC3® family of products offered by Cypress Semiconductor Corporation (San Jose, California). In one embodiment, the core architecture 600 includes a microcontroller 602. The microcontroller 602 includes a CPU (central processing unit) core 604, flash program storage 606, DOC (debug on-chip) 608, a prefetch buffer 610, a private SRAM (static random access memory) 612, and special functions registers 614. In an embodiment, the DOC 608, prefetch buffer 610, private SRAM 612, and special function registers 614 are coupled to the CPU core 604, while the flash program storage 606 is coupled to the prefetch buffer 610.

The core architecture 600 may also include a CHub (core hub) 616, including a bridge 618 and a DMA controller 620 coupled to the microcontroller 602 via bus 622. The CHub 616 may provide the primary data and control interface between the microcontroller 602 and its peripherals and memory, and a programmable core 624. In one embodiment, the control logic 116 of FIG. 1A may be implemented in the core architecture 600, such as part of the programmable core 624. The DMA controller 620 may be programmed to transfer data between system elements without burdening the CPU core 604. In various embodiments, each of these subcomponents of the microcontroller 602 and CHub 616 may be different with each choice or type of CPU core 604. The CHub 616 may also be coupled to a shared SRAM 626 and an SPC (system performance controller) 628. The private SRAM 612 is independent of the shared SRAM 626 accessed by the microcontroller 602 through the bridge 618. The CPU core 604 accesses the private SRAM 612 without going through the bridge 618, thus allowing local register and RAM accesses to occur simultaneously with DMA access to shared SRAM 626. Although labeled here as SRAM, these memory modules may be any suitable type of a wide variety of (volatile or non-volatile) memory or data storage modules in various other embodiments.

In various embodiments, the programmable core 624 may include various combinations of subcomponents (not shown), including, but not limited to, a digital logic array, digital peripherals, analog processing channels, global routing analog peripherals, DMA controller(s), SRAM and other appropriate types of data storage, IO ports, and other suitable types of subcomponents. In one embodiment, the programmable core 624 includes a GPIO (general purpose IO) and EMIF (extended memory interface) block 630 to provide a mechanism to extend the external off-chip access of the microcontroller 602, a programmable digital block 632, a programmable analog block 634, and a special functions block 636, each configured to implement one or more of the subcomponent functions. In various embodiments, the special functions block 636 may include dedicated (non-programmable) functional blocks and/or include one or more interfaces to dedicated functional blocks, such as USB, a crystal oscillator drive, JTAG, and the like.

The programmable digital block 632 may include a digital logic array including an array of digital logic blocks and associated routing. In one embodiment, the digital block architecture is comprised of UDBs (universal digital blocks). For example, each UDB may include an ALU together with CPLD functionality.

In various embodiments, one or more UDBs of the programmable digital block 632 may be configured to perform various digital functions, including, but not limited to, one or more of the following functions: a basic I2C slave; an I2C master; an SPI master or slave; a multi-wire (e.g., 3-wire) SPI master or slave (e.g., MISO/MOSI multiplexed on a single pin); timers and counters (e.g., a pair of 8-bit timers or counters, one 16 bit timer or counter, one 8-bit capture timer, or the like); PWMs (e.g., a pair of 8-bit PWMs, one 16-bit PWM, one 8-bit deadband PWM, or the like), a level-sensitive I/O interrupt generator; a quadrature encoder, a UART (e.g., half-duplex); delay lines; and any other suitable type of digital function or combination of digital functions which can be implemented in a plurality of UDBs.

In other embodiments, additional functions may be implemented using a group of two or more UDBs. Merely for purposes of illustration and not limitation, the following functions can be implemented using multiple UDBs: an I2C slave that supports hardware address detection and the ability to handle a complete transaction without CPU core (e.g., CPU core 604) intervention and to help prevent the force clock stretching on any bit in the data stream; an I2C multi-master which may include a slave option in a single block; an arbitrary length PRS or CRC (up to 32 bits); SDIO; SGPIO; a digital correlator (e.g., having up to 32 bits with 4× over-sampling and supporting a configurable threshold); a LINbus interface; a delta-sigma modulator (e.g., for class D audio DAC having a differential output pair); an I2S (stereo); an LCD drive control (e.g., UDBs may be used to implement timing control of the LCD drive blocks and provide display RAM addressing); full-duplex UART (e.g., 7-, 8- or 9-bit with 1 or 2 stop bits and parity, and RTS/CTS support), an IRDA (transmit or receive); capture timer (e.g., 16-bit or the like); deadband PWM (e.g., 16-bit or the like); an SMbus (including formatting of SMbus packets with CRC in software); a brushless motor drive (e.g., to support 6/12 step commutation); auto BAUD rate detection and generation (e.g., automatically determine BAUD rate for standard rates from 1200 to 115200 BAUD and after detection to generate required clock to generate BAUD rate); and any other suitable type of digital function or combination of digital functions which can be implemented in a plurality of UDBs.

The programmable analog block 634 may include analog resources including, but not limited to, comparators, mixers, PGAs (programmable gain amplifiers), TIAs (trans-impedance amplifiers), ADCs (analog-to-digital converters), DACs (digital-to-analog converters), voltage references, current sources, sample and hold circuits, and any other suitable type of analog resources. The programmable analog block 634 may support various analog functions including, but not limited to, analog routing, LCD drive IO support, capacitance-sensing, voltage measurement, motor control, current to voltage conversion, voltage to frequency conversion, differential amplification, light measurement, inductive position monitoring, filtering, voice coil driving, magnetic card reading, acoustic doppler measurement, echo-ranging, modem transmission and receive encoding, or any other suitable type of analog function.

It should be noted that the embodiments described above use an in-phase signal, opposite phase signal, and a reference signal. The in-phase and opposite phases may be used when using inverters or complementary output stages to generate these signals. Also, the in-phase and opposite phase signals may be used for simplifying the measurement by the ADC as +1 or −1 data signs. However, in other embodiments, different arbitrary phase signals may be used. For example, an in-phase signal and one or more out-of-phase signals may be used.

Embodiments of the present invention, described herein, include various operations. These operations may be performed by hardware components, software, firmware, or a combination thereof. As used herein, the term “coupled to” may mean coupled directly or indirectly through one or more intervening components. Any of the signals provided over various buses described herein may be time-multiplexed with other signals and provided over one or more common buses. Additionally, the interconnection between circuit components or blocks may be shown as buses or as single signal lines. Each of the buses may alternatively be one or more single signal lines and each of the single signal lines may alternatively be buses.

Certain embodiments may be implemented as a computer program product that may include instructions stored on a computer-readable medium. These instructions may be used to program a general-purpose or special-purpose processor to perform the described operations. A computer-readable medium includes any mechanism for storing or transmitting information in a form (e.g., software, processing application) readable by a machine (e.g., a computer). The computer-readable storage medium may include, but is not limited to, magnetic storage medium (e.g., floppy diskette); optical storage medium (e.g., CD-ROM); magneto-optical storage medium; read-only memory (ROM); random-access memory (RAM); erasable programmable memory (e.g., EPROM and EEPROM); flash memory, or another type of medium suitable for storing electronic instructions. The computer-readable transmission medium includes, but is not limited to, electrical, optical, acoustical, or other forms of propagated signal (e.g., carrier waves, infrared signals, digital signals, or the like), or another type of medium suitable for transmitting electronic instructions.

Additionally, some embodiments may be practiced in distributed computing environments where the computer-readable medium is stored on and/or executed by more than one computer system. In addition, the information transferred between computer systems may either be pulled or pushed across the transmission medium connecting the computer systems.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. An integrated circuit comprising:
a plurality of receiver (RX) sensing circuits, each coupled to an RX electrode of a touch panel, wherein each RX sensing circuit comprises:
an attenuator to receive a touch signal from the RX electrode and generate an attenuated current;
a cross-coupled current mirror coupled to the attenuator, the cross-coupled current mirror to output a reverse current of the attenuated current; and
a summer to combine the attenuated current with the reverse current from a neighbor RX sensing circuit of the plurality of RX sensing circuits.

2. The integrated circuit of claim 1, wherein a first RX sensing circuit of the plurality of RX sensing circuits comprises:
a second attenuator to receive the touch signal from a second RX electrode and generate a second attenuated current; and
a second summer to combine the second attenuated current with the reverse current from a neighbor RX sensing circuit of the plurality of RX sensing circuits.

3. The integrated circuit of claim 1, wherein the plurality of RX sensing circuits are ordered serially from a first side of the touch panel to a second side of the touch panel, and wherein the reverse current of each RX sensing circuit is routed to the summer of a neighbor RX sensing circuit in a direction towards the first side.

4. The integrated circuit of claim 3, wherein at least a penultimate RX sensing circuit of the plurality of RX sensing circuits comprises a second cross-coupled current mirror to generate the reverse current from the penultimate RX sensing circuit to the summer of a last RX sensing circuit of the plurality of RX sensing circuits.

5. The integrated circuit of claim 3, wherein each RX sensing circuit further comprises a multiplexer having inputs comprising a first reverse current from the RX sensing circuit and a second reverse current from an immediately preceding RX sensing circuit of the plurality of RX sensing circuits, and wherein an output of the multiplexer is supplied to a sequentially ordered neighbor RX sensing circuit of the plurality of RX sensing circuits.

6. The integrated circuit of claim 1, wherein each cross-coupled current mirror comprises:
a current mirror that outputs an input current to the current mirror; and
a cross-coupled current mirror stage coupled to an output of the current mirror, the cross-coupled current mirror stage having an output comprising the reverse current.

7. The integrated circuit of claim 1, wherein the plurality of RX sensing circuits are ordered serially from a first side of the touch panel to a second side of the touch panel, and wherein the reverse current of each RX sensing circuit is routed to the summer of a neighbor RX sensing circuit in a direction towards the second side.

8. The integrated circuit of claim 7, wherein at least a second RX sensing circuit of the plurality of RX sensing circuits comprises a second cross-coupled current mirror to provide the reverse current from the second RX sensing circuit to a first RX sensing circuit of the plurality of RX sensing circuits.

9. The integrated circuit of claim 7, wherein each RX sensing circuit further comprises a multiplexer having inputs comprising a first reverse current from the RX sensing circuit and a second reverse current from an immediately preceding RX sensing circuit of the plurality of RX sensing circuits, and wherein an output of the multiplexer is supplied to a sequentially ordered neighbor RX sensing circuit of the plurality of RX sensing circuits.

10. The integrated circuit of claim 1, wherein each RX sensing circuit further comprises one of:
a combination of an integrator and an analog-to-digital converter (ADC) coupled to the summer; or
a delta-sigma modulator coupled to the summer.

11. A system comprising:
a touch panel comprising:
a plurality of transmitter (Tx) electrodes; and
a plurality of receiver (RX) electrodes capacitively coupled to the plurality of Tx electrodes; and
a plurality of receiver (RX) sensing circuits, each coupled to a respective RX electrode of the plurality of RX electrodes, wherein each RX sensing circuit comprises:
an attenuator to receive a touch signal from the RX electrode and generate an attenuated current;
a cross-coupled current mirror coupled to the attenuator, the cross-coupled current mirror to output a reverse current of the attenuated current; and
a summer to combine the attenuated current with the reverse current from a neighbor RX sensing circuit of the plurality of RX sensing circuits.

12. The system of claim 11, wherein the plurality of RX sensing circuits are ordered serially from a first side of the touch panel to a second side of the touch panel, and wherein the reverse current of each RX sensing circuit is routed to the summer of a neighbor RX sensing circuit in a direction towards the first side.

13. The system of claim 12, wherein at least a penultimate RX sensing circuit of the plurality of RX sensing circuits comprises a second cross-coupled current mirror to generate the reverse current from the penultimate RX sensing circuit to the summer of a last RX sensing circuit of the plurality of RX sensing circuits.

14. The system of claim 12, wherein each RX sensing circuit further comprises a multiplexer having inputs comprising a first reverse current from the RX sensing circuit and a second reverse current from an immediately preceding RX sensing circuit of the plurality of RX sensing circuits, and wherein an output of the multiplexer is supplied to a sequentially ordered neighbor RX sensing circuit of the plurality of RX sensing circuits.

15. The system of claim 11, wherein each cross-coupled current mirror comprises:
a current mirror that outputs an input current to the current mirror; and
a cross-coupled current mirror stage coupled to an output of the current mirror, the cross-coupled current mirror stage having an output comprising the reverse current.

16. The system of claim 11, wherein the plurality of RX sensing circuits are ordered serially from a first side of the touch panel to a second side of the touch panel, and wherein the reverse current of each RX sensing circuit is routed to the summer of a neighbor RX sensing circuit in a direction towards the second side.

17. The system of claim 16, wherein at least a second RX sensing circuit of the plurality of RX sensing circuits comprises a second cross-coupled current mirror to provide the reverse current from the second RX sensing circuit to a first RX sensing circuit of the plurality of RX sensing circuits.

18. The system of claim 16, wherein each RX sensing circuit further comprises a multiplexer having inputs comprising a first reverse current from the RX sensing circuit and a second reverse current from an immediately preceding RX sensing circuit of the plurality of RX sensing circuits, and wherein an output of the multiplexer is supplied to a sequentially ordered neighbor RX sensing circuit of the plurality of RX sensing circuits.

19. The system of claim 11, wherein each RX sensing circuit further comprises one of:
a combination of an integrator and an analog-to-digital converter (ADC) coupled to the summer; or
a delta-sigma modulator coupled to the summer.

20. A method of reducing self-capacitance of a touch panel, comprising:
generating a reverse current with a cross-coupled current mirror coupled to an attenuator of each of a plurality of receiver (RX) sensing circuits of the touch panel;
routing the reverse current from each RX sensing circuit to a neighbor RX sensing circuit; and
combining, by each respective RX sensing circuit, an attenuated current of a touch signal with the reverse current from a neighbor RX sensing circuit of the plurality of RX sensing circuits.
